(19) United States
(12) Patent Application Publication
(10) Pub. No.: US 2026/0033345 A1
(43) Pub. Date: Jan. 29, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Ping-Tai CHEN, Taipei City (TW); Hung-En HSU, Taipei City (TW); Hsueh-Fu PENG, Taoyuan City (TW); Kuo-Ching HSU, Taipei (TW)

(73) Assignee: Taiwan Semiconductor Manufacturing Company, Ltd., Hsinchu (TW)

(21) Appl. No.: 18/781,467

(22) Filed: Jul. 23, 2024

(51) Int. Cl. H01L 21/48; H01L 23/00; H01L 23/31; H01L 23/498; H01L 23/538; H01L 25/065

(52) U.S. Cl. CPC H01L 21/4857; H01L 21/4864; H01L 23/5383; H01L 24/81; H01L 23/3107; H01L 23/49816; H01L 24/16; H01L 24/32; H01L 24/73; H01L 24/83; H01L 24/92; H01L 25/0655; H01L 2224/16227; H01L 2224/32225; H01L 2224/73204; H01L 2224/81192; H01L 2224/83986; H01L 2224/92125

(57) ABSTRACT

A method for fabricating a package structure is provided. The method includes forming a metal layer over a carrier substrate. The method includes forming a dielectric layer over the metal layer. The method includes forming a plurality of first openings in the dielectric layer. The method includes forming a plurality of second openings in the dielectric layer. The first openings and the second openings expose the metal layer. The method includes forming a conductive material in the first openings and the second openings to form a plurality of conductive features. The method includes removing the metal layer and the carrier substrate. The method includes thinning the dielectric layer around the conductive features. The method also includes bonding a package component to the conductive features.

### BACKGROUND

The semiconductor industry has experienced rapid growth due to ongoing improvements in the integration density of a variety of electronic components (e.g., transistors, diodes, resistors, capacitors, etc.). For the most part, improvements in integration density have resulted from iterative reductions of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

Although existing package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1N illustrates cross-sectional views of intermediate steps during a process for fabricating a package structure in accordance with some embodiments.

FIG. 2 illustrates a partial enlarged view of the package structure in accordance with some embodiments.

FIG. 3 illustrates a partial enlarged view of the package structure in accordance with some embodiments.

FIG. 4 illustrates a cross-sectional view of the package structure in accordance with some embodiments.

FIG. 5 illustrates a cross-sectional view of the package structure in accordance with some embodiments.

FIG. 6 illustrates a cross-sectional view of the package structure in accordance with some embodiments.

FIG. 7 illustrates a cross-sectional view of the package structure in accordance with some embodiments.

FIG. 8 illustrates a cross-sectional view of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and method for fabricating the same are provided. The package structure includes a plurality of conductive features partially exposed form the dielectric layers for electrically connecting the package components. Such conductive features are formed using the method without any photolithography process so as to improve the accuracy of the formation of the conductive features. As a result, the conductive features may be scaled down and the integrated density of the package structure may be increased. In addition, a plurality of dummy conductive features may be formed and protrude from an upper surface of the dielectric layer. The dummy conductive features may serve as a barrier for positioning the package components and confining the molding material within a given region, reducing the risk that the molding material overflows to undesired regions.

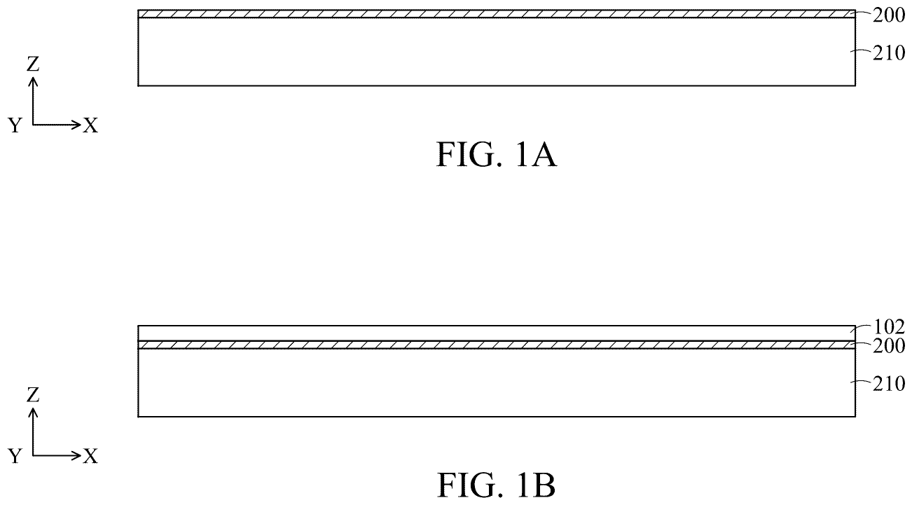

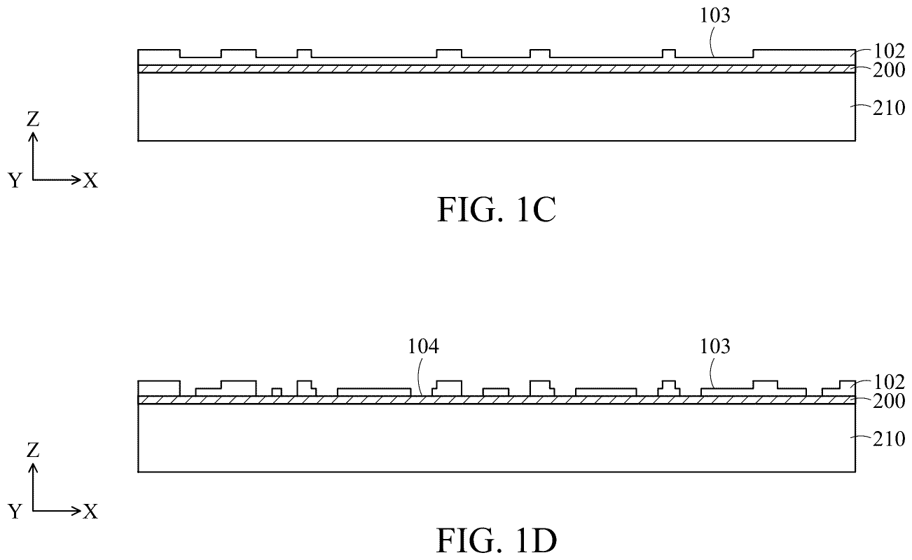

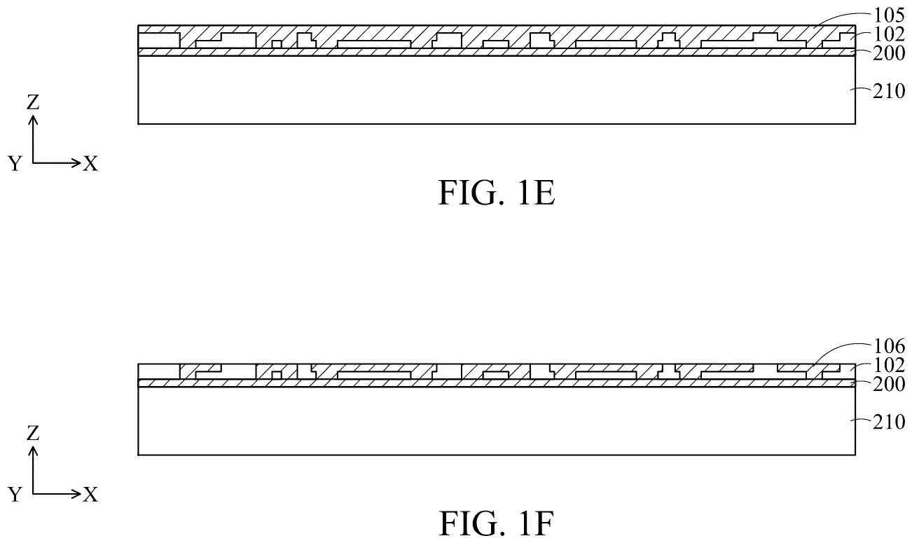

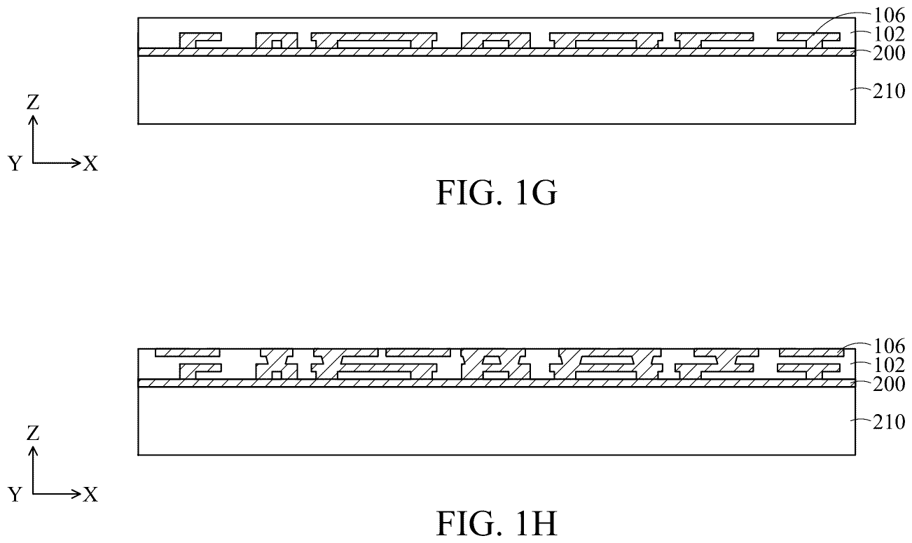

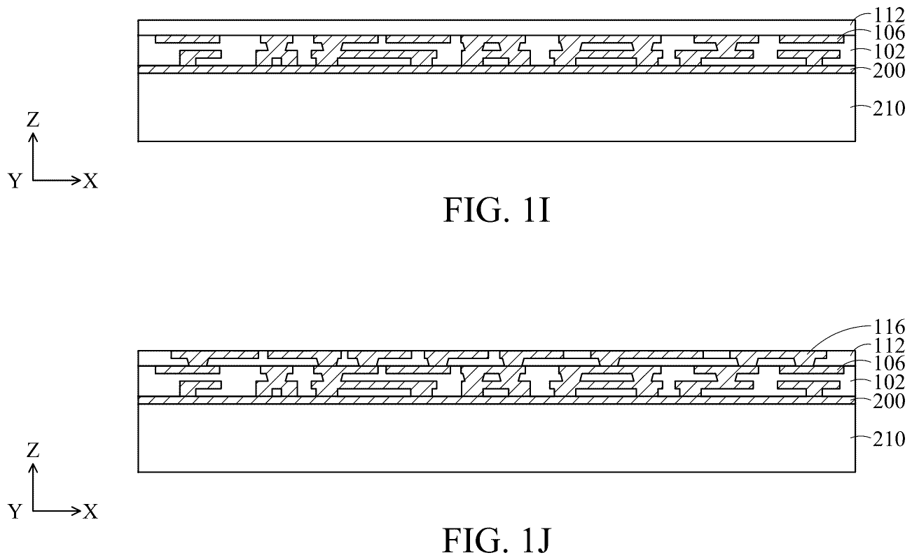

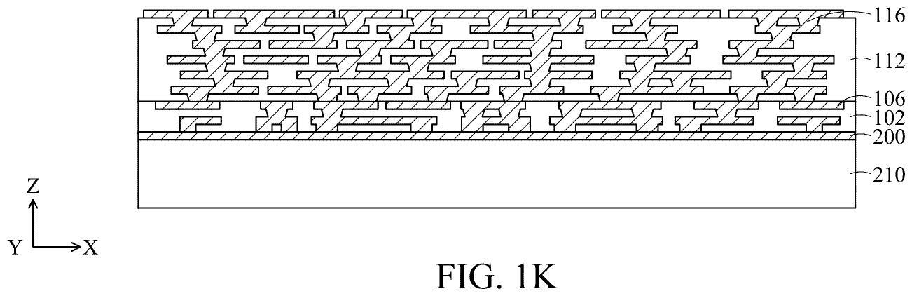

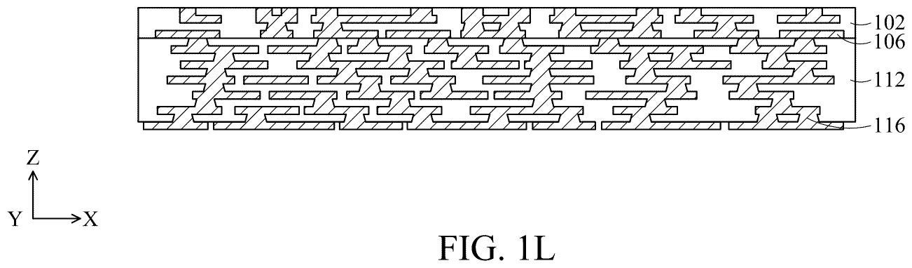

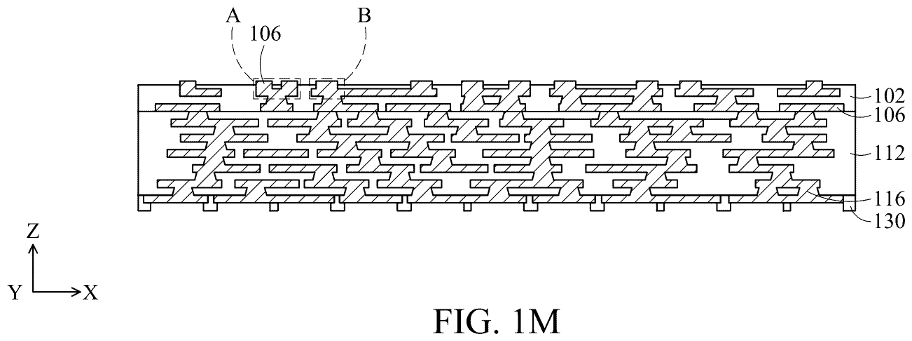

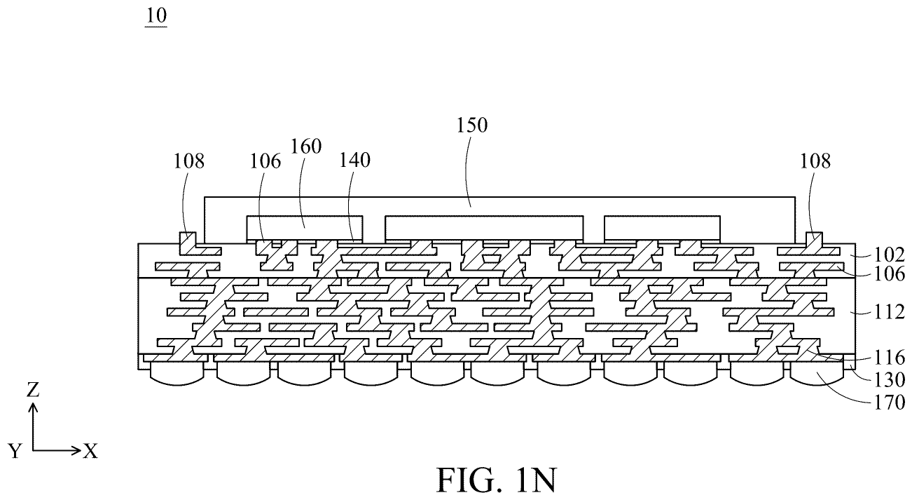

FIGS. 1A through 1N illustrates cross-sectional views of intermediate steps during a process for fabricating a package structure 10 in accordance with some embodiments. As shown in FIG. 1A, a carrier substrate 210 is provided and a metal layer 200 is formed on the carrier substrate 210. For example, the carrier substrate 210 includes or is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. However, the present disclosure is not limited thereto. Alternatively, in some embodiments, the carrier substrate 210 includes or is made of organic materials, glass or any other suitable material. In some embodiments, the metal layer 200 includes a metal, like copper, titanium, tungsten, aluminum, or the like.

Next, as shown in FIG. 1B, a dielectric layer 102 is formed on the metal layer 200. In some embodiments, the dielectric layer 102 completely covers the metal layer 200 for subsequent processes. However, the present disclosure is not limited thereto. In some embodiments, the dielectric layer 102 includes a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), undoped silicate glass (USG), or the like, or a combination thereof. It should be understood that all possible materials for the dielectric layer 102 are included within the scope of the present disclosure. In some embodiments, the dielectric layer 102 is formed, for example, by spin coating, lamination, chemical vapor deposition (CVD), or the like.

Then, as shown in FIG. 1C, a plurality of first openings 103 are formed in the dielectric layer 102. In some embodiments, the first openings 103 are formed by etching, laser drilling, oy any other suitable method. In some embodiments, the widths and the spacings of the first openings 103 may be variant depending upon the interconnect design. That is to say, the dimensions and the locations of the first openings 103 may be adjustable based on the present disclosure. In some embodiments, the first openings 103 may not expose the metal layer 200.

As shown in FIG. 1D, a plurality of second openings 104 are formed in the first openings 103 of the dielectric layer 102. In some embodiments, the second openings 104 are formed by etching, laser drilling, oy any other suitable method. In some embodiments, the widths and the spacings of the second openings 104 may be variant depending upon the interconnect design. That is to say, the dimensions and the locations of the second openings 104 may be adjustable based on the present disclosure. In some embodiments, the first openings 103 and the second openings 104 may expose the metal layer 200. In some embodiments, two or more second openings 104 are formed in single first opening 103, and these second openings 104 are separated from each other. However, the present disclosure.

Next, as shown in FIG. 1E, a conductive material 105 fills into the first openings 103 and the second openings 104. As an example to form the conductive material 105, the conductive material 105 is formed on sidewalls of the dielectric layer 102 in the first openings 103 and the second openings 104 via electroless plating, for example. That is, the conductive material 105 on the sidewalls of the dielectric layer 102 may be in direct contact with the metal layer 200. As a result, it may facilitate to fill the first openings 103 and the second openings 104 with the conductive material 105 in the subsequent process. However, the present disclosure is not limited thereto. Then, the conductive material 105 is filled in the first openings and the second openings after the conductive material 105 is formed on the sidewalls of the dielectric layer 102. In some embodiments, the conductive material 105 may overfill the first openings 103 and the second openings 104 and cover the dielectric layer 102, reducing the risk of voids or defects in the first openings 103 and the second openings 104. However, the present disclosure is not limited thereto.

Next, as shown in FIG. 1F, a planarization process (such as chemical mechanical polishing (CMP), grinding, etc.) may be performed to remove and planarize an upper surface of the conductive material 105. That is, the planarized conductive material 105 may expose the underlying dielectric layer 102 and be referred to as the conductive features 106 in the following paragraphs. Accordingly, in some embodiments, the upper surface of the conductive features 106 may be substantially coplanar with the upper surface of the dielectric layer 102. Using the above-mentioned method without photolithography process to form the conductive features 106 may improve the accuracy of the formation of the conductive features 106. As a result, the conductive features 106 may be scaled down and the integrated density of the package structure 10 may be increased.

As shown in FIG. 1G, another dielectric layer 102 may be formed to cover the underlying conductive features 106 so as to build up the package structure 10 shown in FIG. 1N. For the sake of brevity, the dielectric layers 102 are illustrated as a single-layered structure, and the number of the dielectric layers 102 is not limited in the present disclosure.

As shown in FIG. 1H, another plurality of the conductive features 106 are formed in the dielectric layers 102 and electrically connected to the previously formed conductive features 106. The formation of the conductive features 106 may be referred to the above discussion in company with FIG. 1C-1F, and therefore will not be describe in detail for the sake of brevity. The dimensions and locations of the conductive features 106 may be adjustable based on the present disclosure depending on the interconnect design, and therefore are not limited based on the present disclosure.

Next, as shown in FIG. 1I, a dielectric layer 112 may be formed over the dielectric layer 102. In some embodiments, the dielectric layer 112 includes a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), undoped silicate glass (USG), or the like, or a combination thereof. It should be understood that all possible materials for the dielectric layer 112 are included within the scope of the present disclosure. In some embodiments, the dielectric layer 112 is formed, for example, by spin coating, lamination, chemical vapor deposition (CVD), or the like. In some embodiments, the dielectric layer 112 may be formed using the same method and material as those of the dielectric layer 102. However, the present disclosure is not limited thereto.

Next, as shown in FIG. 1J, a plurality of interconnect patterns 116 are formed in the dielectric layer 112. As an example of the formation of the interconnect patterns 116, a seed layer is formed in the through holes extending through the dielectric layer 112. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the interconnect patterns 116. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the interconnect patterns 116. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

As shown in FIG. 1K, another dielectric layer 112 may be formed to cover the underlying conductive features 116 so as to build up the package structure 10 shown in FIG. 1N. For the sake of brevity, the dielectric layers 112 are illustrated as a single-layered structure, and the number of the dielectric layers 112 is not limited in the present disclosure. Similarly, another plurality of the interconnect patterns 116 are formed in the dielectric layers 112 and electrically connected to the previously formed interconnect patterns 116. The formation of the interconnect patterns 116 may be referred to the above discussion in company with FIG. 1J, and therefore will not be describe in detail for the sake of brevity. The dimensions and locations of the interconnect patterns 116 may be adjustable based on the present disclosure depending on the interconnect design, and therefore are not limited based on the present disclosure. Using the above-mentioned method with photolithography process to form the interconnect patterns 116 may help to reduce process cost in such fan-out structure.

Next, as shown in FIG. 1L, after the dielectric layers 112 and the interconnect patterns 116 are formed, the carrier substrate 210 and the metal layer 200 are removed. In some embodiment, the carrier substrate 210 may be detached from the overall structure and the metal layer 200 may be etched to expose the conductive features 106. It should be noted that the overall structure may be flipped upside-down to perform the removal of the carrier substrate 210 and the metal layer 200. However, the present disclosure is not limited thereto.

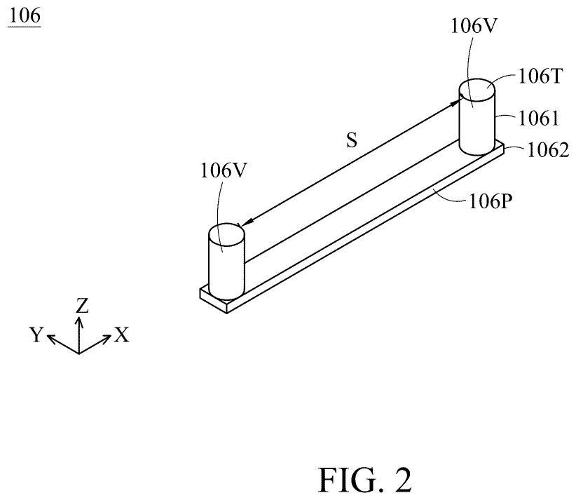

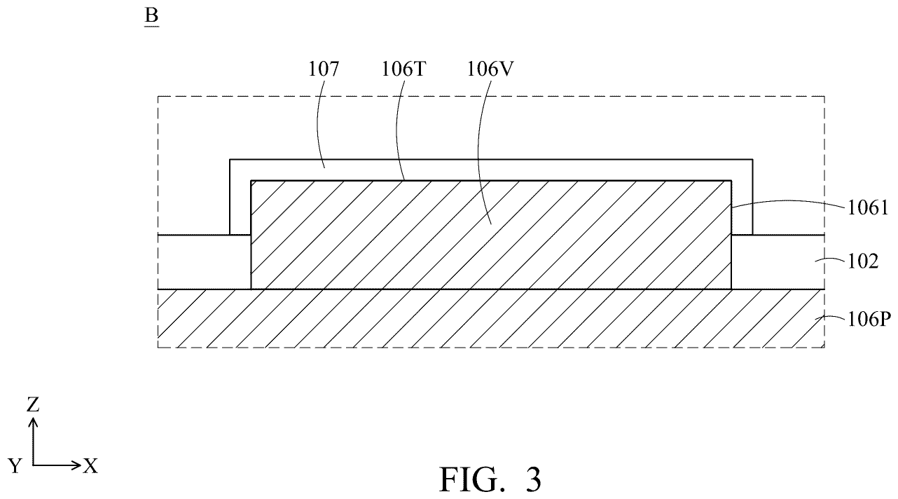

Then, as shown in FIG. 1M, the dielectric layer 102 is thinned down to partially expose sidewalls of the conductive features 106. In some embodiments, the top surface of the dielectric layer 102 may be lower than the top surface (for example, the top surface 106T shown in FIGS. 2 and 3) of the conductive features 106. As a result, subsequent processes may be performed to the conductive features 106 for bonding a plurality of package components 160, as shown in FIG. IN. In some embodiments, the dielectric layer 102 is selectively etched to partially expose sidewalls of the conductive feature 106. In some embodiments, a surface treatment process is performed to the conductive features 106 prior to bonding package components to the conductive features 106. For example, the surface treatment process may include electroless nickel-electroless palladium-immersion gold (ENEPIG) process, organic solderability preservative (OSP) process, or any other suitable process. Accordingly, the risk that oxidation occurs to the conductive features 106 may be reduced, and therefore the performance or reliability of the package structure 10 may be enhanced. In some embodiments, a solder resist layer 130 is selectively formed over the dielectric layer 112. In some embodiments, the solder resist layer 130 is formed to cover the interconnect patterns 116. In some embodiments, the solder resist layer 130 is used to protect the surface of the package structure 10 from external damage. However, the present disclosure is not limited thereto.

Next, as shown in FIG. IN, a plurality of package components 160 are bonded to the conductive features 106. In some embodiments, the package components 160 include a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

In some embodiments, the package components 160 are formed in a wafer, which may include different device regions that are singulated in subsequent steps to form a plurality of integrated circuit dies. In some embodiments, the package components 160 are processed according to applicable manufacturing processes to form integrated circuits. For example, the package components 160 include a semiconductor substrate, such as silicon, doped or undoped, or an active layer of a semiconductor-on-insulator (SOI) substrate. In some embodiments, the semiconductor substrate includes other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the package components 160 are stacked devices that includes multiple semiconductor substrates. For example, the package components 160 may be a memory device such as a hybrid memory cube (HMC) module, a high bandwidth memory (HBM) module, or the like that includes multiple memory dies.

In the embodiment shown, multiple package components 160 are adhered adjacent one another. For example, one of the package components 160 may be a logic device, such as a central processing unit (CPU), a graphics processing unit (GPU), a system-on-a-chip (SoC), a microcontroller, or the like. The other package components 160 may be a memory device, such as a dynamic random access memory (DRAM) die, a static random access memory (SRAM) die, a hybrid memory cube (HMC) module, a high bandwidth memory (HBM) module, or the like. In some embodiments, the package components 160 are the same type of dies, such as SoC dies. In some embodiments, the package components 160 are formed in the processes of the same technology node, or they are formed in the processes of different technology nodes. For example, one of the package components 160 may be of a more advanced process node than the other of the package components 160. The package components 160 may be different sizes (e.g., different heights and/or surface areas), or they may be the same size (e.g., the same height and/or surface area).

Next, as shown in FIG. 1Q, an underfill 140 is formed between the package components 160 and the dielectric layer 102, including between and around the conductive features 106. In some embodiments, the underfill 140 is formed by a capillary flow process after the package components 160 are attached or is formed by a suitable deposition method before the package components 160 are attached. In some embodiments, the underfill 140 is also between the package components 160.

In some embodiments, a molding material 150 is formed around the package components 160, the conductive features 106, and the underfill 140. After formation, the molding material 150 encapsulates the conductive features 106 and the package components 160. In some embodiments, the molding material 150 is a molding compound, epoxy, or the like. In some embodiments, the molding material 150 is applied by compression molding, transfer molding, or the like. In some embodiments, the molding material 150 is applied in liquid or semi-liquid form and then subsequently cured. In some embodiments, a planarization step may be performed to remove and planarize an upper surface of the molding material 150.

In some embodiments, the conductive connectors 170 are formed on the interconnect patterns 116. The conductive connectors 170 may be ball grid array (BGA) connectors, solder balls, controlled collapse chip connection (C4) bumps, micro bumps, electroless nickel-electroless palladium-immersion gold technique (ENEPIG) formed bumps, or the like. In some embodiments, the conductive connectors 170 include a conductive material such as solder, copper, aluminum, gold, nickel, silver, palladium, tin, the like, or a combination thereof. In some embodiments, the conductive connectors 170 are formed by initially forming a layer of solder through evaporation, electroplating, printing, solder transfer, ball placement, or the like. Once a layer of solder has been formed on the structure, a reflow may be performed in order to shape the material into the desired bump shapes. Accordingly, a package structure 10 may be formed.

In some embodiments, the package structure 10 include a plurality of dummy conductive features 108 that is disposed adjacent to and electrically insulated from the conductive features 106. In some embodiments, the dummy conductive features 108 are disposed around and spaced apart from the package components 160. In some embodiments, the dummy conductive features 108 are electrically isolated from the package components 160 and the conductive features 106. In some embodiments, the dummy conductive features 108 protrude from an upper surface of the dielectric layer 102. As a result, the dummy conductive features 108 may serve as a barrier for positioning the package components 160. In some embodiments, the height of the dummy conductive features 108 may be greater than about 3 μm so as to block the molding material 150. To be more specific, the arrangement of the dummy conductive features 108 may help to confine the molding material 150 within a given region, reducing the risk that the molding material 150 overflows to undesired regions. For example, the height of the dummy conductive features 108 may be measured from the upper surface of the dielectric layer 102 in the normal direction of the package structure 10. However, the present disclosure is not limited thereto. In some embodiments, the molding material 150 is spaced apart from the dummy conductive features 180. However, the present disclosure is not limited thereto. In some embodiments, the molding material 150 is in contact with the dummy conductive features 108.

It should be noted that although the package structure 10 is illustrated in FIG. IN, it is not intended to limit the scope of the present disclosure. Those skilled in the art would realize that other components may be added to the package structure 10 for achieving particular function, and these configurations are also included within the scope of the present disclosure.

FIG. 2 illustrates a partial enlarged view of the package structure 10 in accordance with some embodiments. For example, FIG. 2 illustrates the conductive features 106 in the region A, which is shown in FIG. 1M, but the present disclosure is not limited thereto. As shown in FIG. 2, the conductive features 106 include a pad region 106P and a via region 106V connected to the pad portion 106P. In some embodiments, the sidewall 1062 of the pad portion 106P is substantially aligned with the sidewall 1061 of the via portion 106V. To be more specific, the distance between the sidewall 1062 of the pad portion 106P and the sidewall 1061 of the via portion 106V may be less than about 1 μm. Since the conductive features 106 are formed without any photolithography process, the accuracy of the formation of the conductive features 106 can be improved, and there is no need to leave space for alignment of the via region 106V and the pad portion 106P. As a result, the conductive features 106 may be scaled down and the integrated density of the package structure 10 may be increased. In some embodiments, the spacing S between the two adjacent via regions 106V is from about 2 μm to about 10 μm. However, the present disclosure is not limited thereto. The spacing S may be adjustable based on the present disclosure without violating design rules as long as the process conditions permit. In some embodiments, the profile of the via portion 106V of the conductive features 106 is circular in a top view, that is, when viewed in the normal direction (for example, the Z direction) of the package structure 10.

FIG. 3 illustrates a partial enlarged view of the package structure 10 in accordance with some embodiments. For example, FIG. 3 may be illustrated in the region B shown in FIG. 1M. However, the present disclosure is not limited thereto. As shown in FIG. 2, the pad portion 106P is embedded in the dielectric layers 102, and the via portion 106V protrudes over the dielectric layers 102. In some embodiments, a treated portion 107 may be formed on the via portion 106V which is exposed from the dielectric layers 102 due to the surface treatment process. The treated portion 107 may protect the conductive features 106 from oxidation. Accordingly, the width of the via portion 106V over the dielectric layers 102 is greater than the width of the via portion 106V in the dielectric layers 102. That is to say, performing the surface treatment process to the conductive features 106 may laterally widening the conductive features 106. It should be noted that the sidewalls 1061 of the via portion 106V may be vertical, that is for example, parallel to the normal direction (such as the Z direction) of the package structure 10. Accordingly, the stress of the conductive features 106 may be relieved, providing a larger process window. However, the present disclosure is not limited thereto.

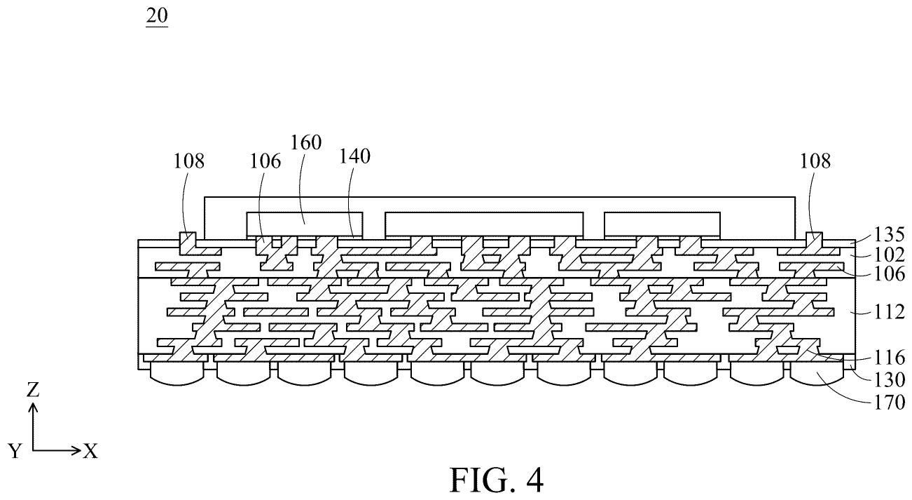

FIG. 4 illustrates a cross-sectional view of the package structure 20 in accordance with some embodiments. It should be noted that the package structure 20 in this embodiment may include the same or similar portions or elements as those of the package structure 10 in FIG. 1. For the sake of brevity, these portions or elements will be denoted as the same or similar numerals, and will not be discussed in detail as follows. As shown in FIG. 4, a solder resist layer 135 is selectively formed over the dielectric layer 102, and the conductive features 106 protrude over the solder resist layer 135 so as to electrically connect the package component 160. In some embodiments, the solder resist layer 135 is used to protect the surface of the package structure 10 from external damage. However, the present disclosure is not limited thereto.

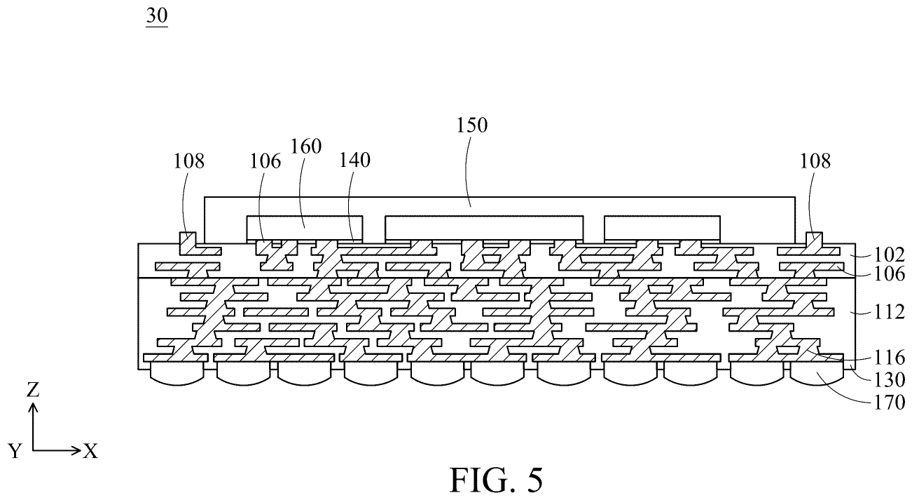

FIG. 5 illustrates a cross-sectional view of the package structure 30 in accordance with some embodiments. It should be noted that the package structure in this embodiment may include the same or similar portions or elements as those of the package structure 10 in FIG. 1. For the sake of brevity, these portions or elements will be denoted as the same or similar numerals, and will not be discussed in detail as follows. As shown in FIG. 5, the solder resist layer 130 is omitted, and the dielectric layers 112 may be formed over the interconnect patterns 116. To be more specific, the dielectric layers 112 include a plurality of openings for forming the conductive connectors 170. However, the present disclosure is not limited thereto.

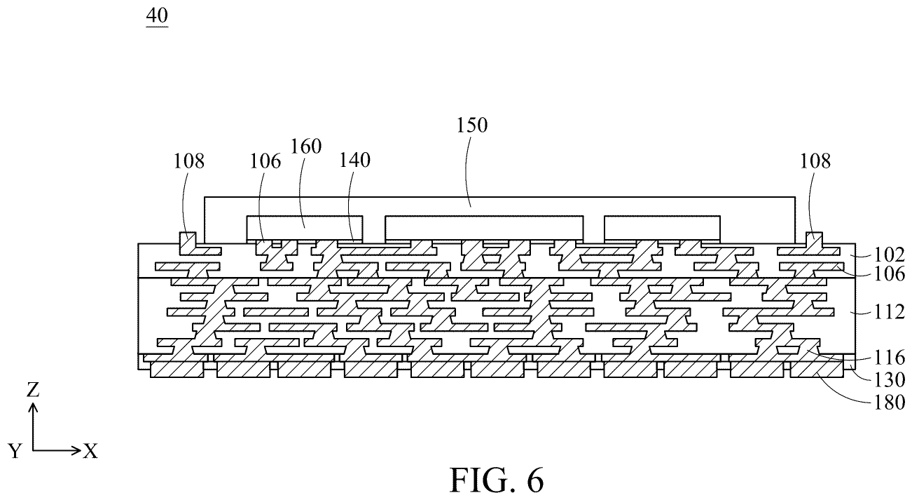

FIG. 6 illustrates a cross-sectional view of the package structure 40 in accordance with some embodiments. It should be noted that the package structure 40 in this embodiment may include the same or similar portions or elements as those of the package structure 10 in FIG. 1. For the sake of brevity, these portions or elements will be denoted as the same or similar numerals, and will not be discussed in detail as follows. For example, the package structure 40 includes a plurality of metal bumps 180 to replace the conductive connectors 170. As an example to form the metal bumps 180, a seed layer is formed in the openings of the solder resist layer 130. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metal bumps 180. With the arrangement of the metal bumps 180, the stress between the metal bumps 180 and the solder resist layer 130 may be relieved, providing a larger process window since the sidewalls of the metal bumps 180 may be vertical, that is for example, parallel to the normal direction (such as the Z direction) of the package structure 40. However, the present disclosure is not limited thereto.

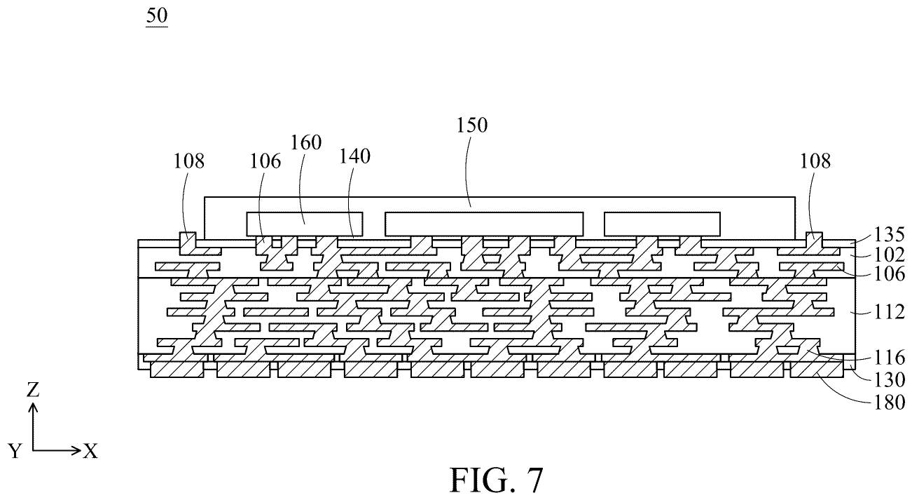

FIG. 7 illustrates a cross-sectional view of the package structure 50 in accordance with some embodiments. It should be noted that the package structure 50 in this embodiment may include the same or similar portions or elements as those of the package structure 20 in FIG. 4. For the sake of brevity, these portions or elements will be denoted as the same or similar numerals, and will not be discussed in detail as follows. For example, the package structure 50 includes a plurality of metal bumps 180 to replace the conductive connectors 170 so as to relieve the stress between the metal bumps 180 and the solder resist layer 130 and provides a larger process window. However, the present disclosure is not limited thereto.

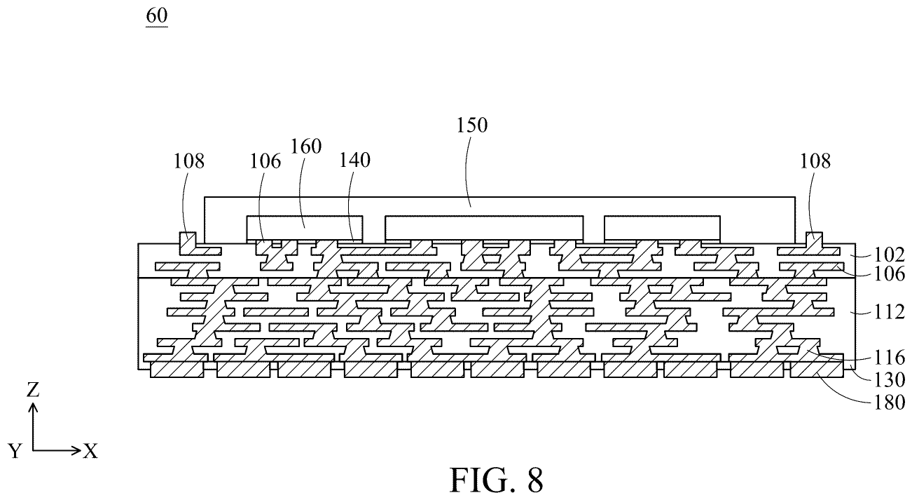

FIG. 8 illustrates a cross-sectional view of the package structure 60 in accordance with some embodiments. It should be noted that the package structure 60 in this embodiment may include the same or similar portions or elements as those of the package structure 30 in FIG. 5. For the sake of brevity, these portions or elements will be denoted as the same or similar numerals, and will not be discussed in detail as follows. For example, the package structure 60 includes a plurality of metal bumps 180 to replace the conductive connectors 170 so as to relieve the stress between the metal bumps 180 and the dielectric layers 112 and provides a larger process window. However, the present disclosure is not limited thereto.

Embodiments of package structures and method for fabricating the same are provided. The package structure includes a plurality of conductive features partially exposed form the dielectric layers for electrically connecting the package components. Such conductive features are formed using the method without any photolithography process so as to improve the accuracy of the formation of the conductive features. As a result, the conductive features may be scaled down and the integrated density of the package structure may be increased. In particular, each of the conductive features includes a pad portion and a via portion connected to the pad portion, and the sidewall of the pad portion is substantially aligned with the sidewall of the via portion. In addition, a plurality of dummy conductive features may be formed and protrude from an upper surface of the dielectric layer. The dummy conductive features may serve as a barrier for positioning the package components and confining the molding material within a given region, reducing the risk that the molding material overflows to undesired regions.

In some embodiments, a method for fabricating a package structure is provided. The method includes forming a metal layer over a carrier substrate. The method includes forming a dielectric layer over the metal layer. The method includes forming a plurality of first openings in the dielectric layer. The method includes forming a plurality of second openings in the dielectric layer. The first openings and the second openings expose the metal layer. The method includes forming a conductive material in the first openings and the second openings to form a plurality of conductive features. The method includes removing the metal layer and the carrier substrate. The method includes thinning the dielectric layer around the conductive features. The method also includes bonding a package component to the conductive features.

In some embodiments, a package structure is provided. The package structure includes a plurality of interconnect patterns embedded in a plurality of dielectric layers. The package structure includes a plurality of conductive features partially exposed form the dielectric layers and electrically connected to the interconnect patterns. Each of the conductive features includes a pad portion in the dielectric layers and a via portion protruding over the dielectric layers and connected to the pad portion. The sidewall of the pad portion is substantially aligned with the sidewall of the via portion. The package structure includes a package component bonded to the interconnect structure via the conductive features. The package structure also includes a molding material over the dielectric layers and encapsulating the conductive features and the package component.

In some embodiments, a method for fabricating a package structure is provided. The method includes forming a metal layer over a carrier substrate. The method includes forming a dielectric layer over the metal layer. The method includes forming a first opening in the dielectric layer. The method includes forming a plurality of second openings in the first opening. The second openings are separated from each other. The method includes forming a conductive material in the first openings and the second openings to form a conductive feature. The conductive feature is in contact with the metal layer. The method includes removing the metal layer and the carrier substrate to expose a top surface of the conductive feature. The method includes selectively etching the dielectric layer to partially expose sidewalls of the conductive feature. The method also includes bonding a package component to the conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a package structure, comprising:
forming a metal layer over a carrier substrate;
forming a dielectric layer over the metal layer;
forming a plurality of first openings in the dielectric layer;
forming a plurality of second openings in the dielectric layer, wherein the first openings and the second openings expose the metal layer;
forming a conductive material in the first openings and the second openings to form a plurality of conductive features;
removing the metal layer and the carrier substrate;
thinning the dielectric layer around the conductive features; and
bonding a package component to the conductive features.

2. The method as claimed in claim 1, wherein a width of the first openings is different from a width of the second openings.

3. The method as claimed in claim 1, wherein forming the conductive material in the first openings and the second openings further comprises:
forming the conductive material on sidewalls of the dielectric layer in the first openings and the second openings via electroless plating; and
filling the conductive material in the first openings and the second openings after the conductive material is formed on the sidewalls of the dielectric layer.

4. The method as claimed in claim 1, wherein thinning the dielectric layer around the conductive features comprising selectively etching the dielectric layer and partially exposing sidewalls of the conductive features.

5. The method as claimed in claim 1, further comprising:
forming a solder resist layer on the dielectric layer and around the conductive features.

6. The method as claimed in claim 1, further comprising:
performing a surface treatment process to the conductive features prior to bonding the package component to the conductive features.

7. The method as claimed in claim 6, wherein performing the surface treatment process to the conductive features comprises laterally widening the conductive features.

8. A package structure, comprising:
a plurality of interconnect patterns embedded in a plurality of dielectric layers;
a plurality of conductive features partially exposed form the dielectric layers and electrically connected to the interconnect patterns, wherein each of the conductive features comprises:
a pad portion in the dielectric layers; and
a via portion protruding over the dielectric layers and connected to the pad portion, wherein a sidewall of the pad portion is substantially aligned with a sidewall of the via portion;
a package component bonded to the interconnect structure via the conductive features; and
a molding material over the dielectric layers and encapsulating the conductive features and the package component.

9. The package structure as claimed in claim 8, further comprising:
a solder resist layer over the plurality of dielectric layers and exposing the conductive features, wherein the via portion of each of the conductive features extends through the solder resist layer.

10. The package structure as claimed in claim 8, wherein a width of the via portion over the dielectric layers is greater than a width of the via portion in the dielectric layers.

11. The package structure as claimed in claim 8, wherein the spacing between the two adjacent via portions is from about 2 μm to about 10 μm.

12. The package structure as claimed in claim 8, further comprising:
a plurality of dummy conductive features disposed adjacent to and electrically insulated from the conductive features.

13. The package structure as claimed in claim 12, wherein the dummy conductive features are spaced apart from the package component.

14. The package structure as claimed in claim 12, wherein the molding material is spaced apart from the dummy conductive features.

15. The package structure as claimed in claim 12, wherein the molding material is in contact with the dummy conductive features.

16. The package structure as claimed in claim 8, wherein a profile of the via portion of the conductive features is circular in a top view.

17. A method for fabricating a package structure, comprising:
forming a metal layer over a carrier substrate;
forming a dielectric layer over the metal layer;
forming a first opening in the dielectric layer;
forming a plurality of second openings in the first opening, wherein the second openings are separated from each other;
forming a conductive material in the first openings and the second openings to form a conductive feature, wherein the conductive feature is in contact with the metal layer;
removing the metal layer and the carrier substrate to expose a top surface of the conductive feature;
selectively etching the dielectric layer to partially expose sidewalls of the conductive feature; and
bonding a package component to the conductive feature.

18. The method as claimed in claim 17, further comprising:
forming a plurality of metal bumps over the dielectric layer, wherein the conductive feature is electrically connected to the metal bumps.

19. The method as claimed in claim 18, further comprising:
forming a solder resist layer over the dielectric layer and around the metal bumps.

20. The method as claimed in claim 17, further comprising:
performing a surface treatment process to the conductive feature after the top surface and the sidewalls of the conductive feature are exposed.
